(19) United States
(12) Patent Application Publication
(10) Pub. No.: US 2026/0088087 A1
(43) Pub. Date: Mar. 26, 2026

(54) SEMICONDUCTOR DEVICE, METHOD OF OPERATING THEREOF, SYSTEM, AND COMPUTER-READABLE STORAGE MEDIUM

(71) Applicant: Yangtze Memory Technologies Holding Co., Ltd., Wuhan (CN)

(72) Inventors: Xinran Li, Wuhan (CN); Feng Xu, Wuhan (CN); Da Li, Wuhan (CN); Lei Jin, Wuhan (CN); Zongliang Huo, Wuhan (CN)

(21) Appl. No.: 19/237,809

(22) Filed: Jun. 13, 2025

Related U.S. Application Data
(63) Continuation of application No. PCT/CN2025/082924, filed on Mar. 17, 2025.

(30) Foreign Application Priority Data
Sep. 25, 2024 (CN) 202411346247.9

(51) Int. Cl. G11C 16/04; G11C 7/16; G11C 16/08; G11C 16/10; H01L 23/00; H01L 25/065; H01L 25/18; H10B 80/00

(52) U.S. Cl. CPC G11C 16/0483; G11C 7/16; G11C 16/08; G11C 16/10; H10B 80/00; H10W 90/00; H10W 90/792

(57) ABSTRACT

According to one aspect of the present disclosure, a semiconductor device is provided. The semiconductor device may include a memory array comprising a first memory string and a second memory string. The first memory string may include at least one first dummy memory cell. The semiconductor device may include a peripheral circuit coupled to the memory array and configured to perform a program operation on the at least one first dummy memory cell, such that a threshold voltage of the at least one first dummy memory cell is adjusted from an initial threshold to a first target threshold. In a case where the threshold voltage of the at least one first dummy memory cell reaches the first target threshold, a difference between a current of the first memory string and a current of the second memory string may be less than or equal to a preset threshold.

### CROSS-REFERENCE TO RELATED APPLICATIONS

This application is a continuation of International Application No. PCT/CN2025/082924, filed on Mar. 17, 2025, which claims the benefit of priority to Chinese Application No. 202411346247.9, filed on Sep. 25, 2024, both which are hereby incorporated by reference in their entireties.

### TECHNICAL FIELD

The present disclosure relates to, but is not limited to, a semiconductor device and an operation method thereof, a system, and a computer-readable storage medium.

### BACKGROUND

In a classical von Neumann computing architecture, a memory and a processor are separate, and data transmission is performed between the memory and processor through a data bus. The processor first reads data from the memory when executing the command, and writes the updated data back to the memory after processing. However, frequent data migration causes huge power consumption and time overhead; in addition, due to limited memory bandwidth, the processing speed of the processor is limited by the access speed of the memory, which greatly affects the computing performance. With the rise of applications such as big data and artificial intelligence, processing of massive data makes the bottleneck of the Von Neumann computing architecture increasingly prominent.

### SUMMARY

According to one aspect of the present disclosure, a semiconductor device is provided. The semiconductor device may include a memory array including a first memory string and a second memory string. The first memory string may include at least one first dummy memory cell. The semiconductor device may include a peripheral circuit coupled to the memory array and configured to perform a program operation on the at least one first dummy memory cell, such that a threshold voltage of the at least one first dummy memory cell is adjusted from an initial threshold to a first target threshold. In a case where the threshold voltage of the at least one first dummy memory cell reaches the first target threshold, a difference between a current of the first memory string and a current of the second memory string may be less than or equal to a preset threshold.

In some implementations, the second memory string includes at least one second dummy memory cell. In some implementations, a threshold voltage of the at least one second dummy memory cell may remain at the initial threshold. In some implementations, before performing the program operation on the at least one first dummy memory cell, the current of the first memory string may be greater than the current of the second memory string. In some implementations, the difference between the current of the first memory string and the current of the second memory string may be greater than the preset threshold.

In some implementations, the second memory string may include at least one second dummy memory cell. In some implementations, the peripheral circuit may be configured to perform a program operation on the at least one second dummy memory cell, such that a threshold voltage of the at least one second dummy memory cell is adjusted from the initial threshold to a second target threshold. In some implementations, in a case where the threshold voltage of the at least one first dummy memory cell reaches the first target threshold and the threshold voltage of the at least one second dummy memory cell reaches the second target threshold, the difference between the current of the first memory string and the current of the second memory string may be less than or equal to the preset threshold.

In some implementations, the first target threshold may be equal to the second target threshold.

In some implementations, the first target threshold may be greater than the second target threshold. In some implementations, before performing the program operation on the at least one first dummy memory cell and the at least one second dummy memory cell, the current of the first memory string may be greater than the current of the second memory string. In some implementations, the difference between the current of the first memory string and the current of the second memory string may be greater than the preset threshold.

In some implementations, the peripheral circuit may be further configured to apply a read voltage to a target word line in a target memory block. In some implementations, the peripheral circuit may be further configured to apply a first pass voltage to a non-target word line in the target memory block. In some implementations, the peripheral circuit may be further configured to apply respective input voltages to a plurality of first select lines in the target memory block respectively. In some implementations, the peripheral circuit may be further configured to apply a second pass voltage to a plurality of second select lines in the target memory block respectively. In some implementations, the peripheral circuit may be further configured to sense a current on a bit line coupled to the target memory block to obtain a current of a memory string in the target memory block. In some implementations, the target memory block may include the first memory string and the second memory string.

In some implementations, the peripheral circuit may be further configured to apply a respective input voltage to the first select line coupled to one memory string in the target memory block to turn on the memory string. In some implementations, the peripheral circuit may be further configured to apply respective input voltages to the first select lines coupled to other memory strings coupled to the same bit line to which the memory string is coupled to turn off the other memory strings.

In some implementations, the target memory block may include a plurality of memory cells. In some implementations, the memory cell may be configured to store N bits of weight data. In some implementations, the plurality of memory cells in the target memory block may be configured to have 2^{N} memory states. In some implementations, the read voltage may be between threshold voltage distributions corresponding to two adjacent memory states. In some implementations, N may be an integer greater than or equal to 1.

In some implementations, the first select line may be one of a top select line and a bottom select line, and the second select line may be the other of the top select line and the bottom select line.

In some implementations, the peripheral circuit may include an analog-to-digital conversion circuit, a digital-to-analog conversion circuit, a voltage generator, a column decoder, and a control logic. In some implementations, the analog-to-digital conversion circuit may be coupled to the column decoder and the control logic. In some implementations, the digital-to-analog conversion circuit may be coupled to the voltage generator and the control logic.

In some implementations, the semiconductor device may include a three-dimensional NAND memory.

In some implementations, the semiconductor device may include a first semiconductor structure, a hybrid bonding layer, and a second semiconductor structure that are stacked in a thickness direction of the semiconductor device, with the hybrid bonding layer located between the first semiconductor structure and the second semiconductor structure. In some implementations, the memory array may be located in the first semiconductor structure. In some implementations, the peripheral circuit may be located in the second semiconductor structure. In some implementations, the memory array and the peripheral circuit may be coupled through a bonding structure in the hybrid bonding layer.

According to another aspect of the present disclosure, a system is provided. The system may include at least one semiconductor device. The at least one semiconductor device may include a memory array including a first memory string and a second memory string. The first memory string may include at least one first dummy memory cell. The at least one semiconductor device may include a peripheral circuit coupled to the memory array and configured to perform a program operation on the at least one first dummy memory cell, such that a threshold voltage of the at least one first dummy memory cell is adjusted from an initial threshold to a first target threshold. In a case where the threshold voltage of the at least one first dummy memory cell reaches the first target threshold, a difference between a current of the first memory string and a current of the second memory string may be less than or equal to a preset threshold. The system may include a controller coupled to the at least one semiconductor device and configured to send input data to the semiconductor device and receive an operation result of the semiconductor device.

According to a further aspect of the present disclosure, a method of operating a semiconductor device. The performing a program operation on at least one first dummy memory cell included in a first memory string included in the semiconductor device, such that a threshold voltage of the at least one first dummy memory cell may be adjusted from an initial threshold to a first target threshold. In a case where the threshold voltage of the at least one first dummy memory cell reaches the first target threshold, a difference between a current of the first memory string and a current of a second memory string included in the semiconductor device may be less than or equal to a preset threshold.

In some implementations, the method may include causing a threshold voltage of at least one second dummy memory cell included in the second memory string included in the semiconductor device to remain at the initial threshold. In some implementations, before performing the program operation on the at least one first dummy memory cell, the current of the first memory string is greater than the current of the second memory string, and the difference between the current of the first memory string and the current of the second memory string may be greater than the preset threshold.

In some implementations, the method may include performing a program operation on at least one second dummy memory cell included in the second memory string, such that a threshold voltage of the at least one second dummy memory cell is adjusted from the initial threshold to a second target threshold. In some implementations, in a case where the threshold voltage of the at least one first dummy memory cell reaches the first target threshold and the threshold voltage of the at least one second dummy memory cell reaches the second target threshold, the difference between the current of the first memory string and the current of the second memory string may be less than or equal to the preset threshold.

In some implementation, the first target threshold may be equal to the second target threshold.

In some implementation, the first target threshold may be greater than the second target threshold. In some implementation, before performing the program operation on the at least one first dummy memory cell and the at least one second dummy memory cell, the current of the first memory string may be greater than the current of the second memory string, and the difference between the current of the first memory string and the current of the second memory string may be greater than the preset threshold.

In some implementation, the method may include applying a read voltage to a target word line in a target memory block included in the semiconductor device. In some implementation, the method may include applying a first pass voltage to a non-target word line in the target memory block. In some implementation, the method may include applying respective input voltages to a plurality of first select lines in the target memory block respectively. In some implementation, the method may include applying a second pass voltage to a plurality of second select lines in the target memory block. In some implementation, the method may include sensing a current on a bit line coupled to the target memory block to obtain a current of a memory string in the target memory block. In some implementations, the target memory block may include the first memory string and the second memory string.

In some implementations, the applying the respective input voltages to the plurality of first select lines in the target memory block respectively may include applying a respective input voltage to the first select line coupled to one memory string in the target memory block to turn on the memory string. In some implementations, the applying the respective input voltages to the plurality of first select lines in the target memory block respectively may include applying respective input voltages to the first select lines coupled to other memory strings coupled to the same bit line to which the memory string is coupled to turn off the other memory strings.

In some implementations, the target memory block may include a plurality of memory cells. In some implementations, the memory cells may be configured to store N bits of weight data. In some implementations, the plurality of memory cells may be configured to have 2^{N} memory states. In some implementations, the read voltage may be between threshold voltage distributions corresponding to two adjacent memory states. In some implementations, N may be an integer greater than or equal to 1.

According to still another aspect of the present disclosure, a computer-readable storage medium storing a computer program thereon. When the computer program is executed by a processor, an operation method of a semiconductor device may be performed. The method may include performing a program operation on at least one first dummy memory cell included in a first memory string included in the semiconductor device, such that a threshold voltage of the at least one first dummy memory cell is adjusted from an initial threshold to a first target threshold. In a case where the threshold voltage of the at least one first dummy memory cell reaches the first target threshold, a difference between a current of the first memory string and a current of a second memory string included in the semiconductor device may be less than or equal to a preset threshold.

In the technical solutions provided by the present disclosure, the peripheral circuit is configured to adjust a resistance of the memory string by adjusting the threshold voltage of the dummy memory cell in the memory string, so that the differences between the currents of different memory strings are all less than the preset threshold. Thus, in a stage of using the semiconductor devices for operation, the output currents of different memory strings in a turn-on state may be substantially equal, thereby improving the reliability of the operation result of a multiply accumulate operation obtained based on multiple of the current on the bit line relative to the output current of a single memory string.

### BRIEF DESCRIPTION OF THE DRAWINGS

FIG. 1 is a first schematic diagram of a system according to an example of the present disclosure;

FIG. 2 is a second schematic diagram of a system according to an example of the present disclosure;

FIG. 3 is a schematic diagram of a memory card according to an example of the present disclosure;

FIG. 4 is a schematic diagram of a solid state disk according to an example of the present disclosure;

FIG. 5 is a first schematic diagram of composition of a semiconductor device according to an example of the present disclosure;

FIG. 6 is a second schematic diagram of composition of a semiconductor device according to an example of the present disclosure;

FIG. 7 is a schematic diagram of inputting an input voltage by a word line into a memory block according to an example of the present disclosure;

FIG. 8 is a schematic diagram of inputting an input voltage by a top select line into a memory block according to an example of the present disclosure;

FIG. 9 is a schematic diagram of threshold voltage distributions of memory cells coupled to a target word line according to an example of the present disclosure;

FIG. 10 is a schematic diagram of a plurality of memory strings coupled to a bit line according to an example of the present disclosure;

FIG. 11 is a schematic diagram of measuring a current of a memory string according to an example of the present disclosure;

FIG. 12 is a first current-voltage curve according to an example of the present disclosure;

FIG. 13 is a schematic diagram after a program operation is performed on a first dummy memory cell according to an example of the present disclosure;

FIG. 14 is a first schematic diagram after a program operation is performed on a first dummy memory cell and a second dummy memory cell according to an example of the present disclosure;

FIG. 15 is a second current-voltage curve according to an example of the present disclosure;

FIG. 16 is a second schematic diagram after performing a program operation on a first dummy memory cell and a second dummy memory cell according to an example of the present disclosure;

FIG. 17 is a schematic diagram of a computer-readable storage medium according to an example of the present disclosure.

### DETAILED DESCRIPTION

Example implementations of the present disclosure will be described in more detail below with reference to the accompanying drawings. Although the example implementations of the present disclosure are shown in the drawings, it should be understood that the present disclosure may be implemented in various forms and should not be limited by the implementations set forth herein. On the contrary, these implementations are provided to enable a more thorough understanding of the present disclosure and to fully convey the scope of the present disclosure to those skilled in the art.

In the following description, numerous specific details are set forth in order to provide a more thorough understanding of the present disclosure. However, it will be apparent to those skilled in the art that the present disclosure may be practiced without one or more of these details. In other examples, in order to avoid confusion with the present disclosure, some technical features known in the art are not described; that is, not all features of actual examples are described herein, and well-known functions and structures are not described in detail.

In the drawings, the sizes of layers, regions, elements and their relative sizes may be exaggerated for clarity. Like numbers refer to like elements throughout.

It will be understood that when an element or layer is referred to as being “on”, “adjacent to”, “connected to” or “coupled to” another element or layer, it can be directly on, adjacent to, connected or coupled to the other element or layer, or intervening elements or layers may be present. In contrast, when an element is referred to as being “directly on,” “directly adjacent to,” “directly connected to,” or “directly coupled to” another element or layer, there are no intervening elements or layers present. It will be understood that, although the terms first, second, third, etc. may be used to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure. When a second element, component, region, layer or section is discussed, it does not indicate that the first element, component, region, layer or section is necessarily present in the present disclosure.

Spatially relative terms, such as “under”, “below”, “lower”, “beneath”, “above”, “upper” and the like, may be used herein for ease of description to describe one element or feature's relationship to another element(s) or feature(s) as illustrated in the figures. It will be understood that the spatially relative terms may encompass different orientations of the device in use or operation in addition to the orientation depicted in the figures. For example, if the device in the figures is turned over, elements or features described as “below” or “under” or “beneath” other elements would then be oriented as “above” the other elements or features. Thus, the exemplary terms “below” and “under” can encompass both above and below orientations. The device may be otherwise oriented (rotated 90 degrees or at other orientations) and the spatially relative descriptors used herein interpreted accordingly.

The terminology used herein is for the purpose of describing particular examples only and is not intended to be limiting of the disclosure. As used herein, the singular forms “a”, “an” and “the” are intended to include the plural forms as well, unless the context clearly indicates otherwise. It will be further understood that the terms “comprise” and/or “include” when used in this specification, specify the presence of stated features, integers, steps, operations, elements, and/or components, but do not preclude the presence or addition of one or more other features, integers, steps, operations, elements, components, and/or combinations thereof. As used herein, the term “and/or” includes any and all combinations of the associated listed items.

In order to understand the features and technical contents of the examples of the present disclosure in more detail, the implementations of the examples of the present disclosure are described in detail below with reference to the accompanying drawings, and the accompanying drawings are for reference only and are not intended to limit the examples of the present disclosure.

In a classical von Neumann computing architecture, a memory for storing data is separate from a processor for data processing, and data is transmitted between the two through a data bus. When executing a data processing command, the processor needs to first read data from the memory, and then write the updated data back to the memory after processing, which requires data to be frequently transmitted between the memory and the processor, resulting in huge power consumption and time overhead. In addition, due to the limited bandwidth of the memory, the processing speed of the processor is limited by the access speed of the memory, thereby limiting the improvement of the computing performance. With the rise of application fields such as big data and artificial intelligence, processing demands for massive data have make the bottleneck of the Von Neumann computing architecture increasingly prominent.

In order to solve the bottleneck of the classical von Neumann computing architecture, the compute-in-memory chip architecture has emerged. Its basic idea is to directly use the memory for logic computing, thereby reducing the overhead caused by frequent data transmission between the memory and the processor, and improving computing performance while reducing power consumption.

The compute-in-memory chip has both storage capability and computing capability relying on its own physical characteristics. The storage capability refers to the capability to store values by changing conductance of memory cells according to physical characteristics of the memory cells of different types of memories. The computing capability refers to the capability to perform a multiply accumulate (MAC) operation according to Ohm's law and Kirchhoff's law by constructing an array composed of the memory cells.

In some implementations, for the compute-in-memory chip, a weight matrix may be stored in a memory array according to a certain mapping rule by changing the conductance of the memory cells, and in an example, the conductance of each memory cell may represent a weight in the weight matrix. After the weight matrix is written into the memory array, an element in an input vector may be mapped to a voltage value of an input end of the memory array. Taking a case in which a plurality of elements in the input vector are mapped to input voltages of a plurality of rows as an example, based on Ohm's law, a current output by each memory cell in the memory array represents the result of multiplying an element in the input vector by a weight; and based on Kirchhoff's law, currents output by a column of memory cells may be accumulated to obtain a calculation result of accumulating and summing a plurality of multiply results, and the calculation result output by the column of memory cells may correspond to one element in the output vector, and then the calculation result of the weight matrix and the input vector may be output through the memory array including the plurality of columns of memory cells. Therefore, the memory array in the compute-in-memory chip not only stores the weight matrix, implements a storage function, but also implements a computing function.

In some examples, the compute-in-memory chip may include one of memories such as a Static Random Access Memory (SRAM), a Dynamic Random Access Memory (DRAM), a Phase-Change Memory (PCM), and a NAND flash memory. Among them, the NAND flash memory is a non-volatile memory having a large storage capacity, especially a three-dimensional NAND memory with a three-dimensional structure has a high storage density and has the potential to be developed as an compute-in-memory chip. In the following, related content of the three-dimensional NAND memory will be introduced.

In some examples, a system including a three-dimensional NAND memory includes a semiconductor device and a controller coupled with the semiconductor device. The controller is configured to send an input vector or an input matrix to the semiconductor device and receive an operation result of the semiconductor device.

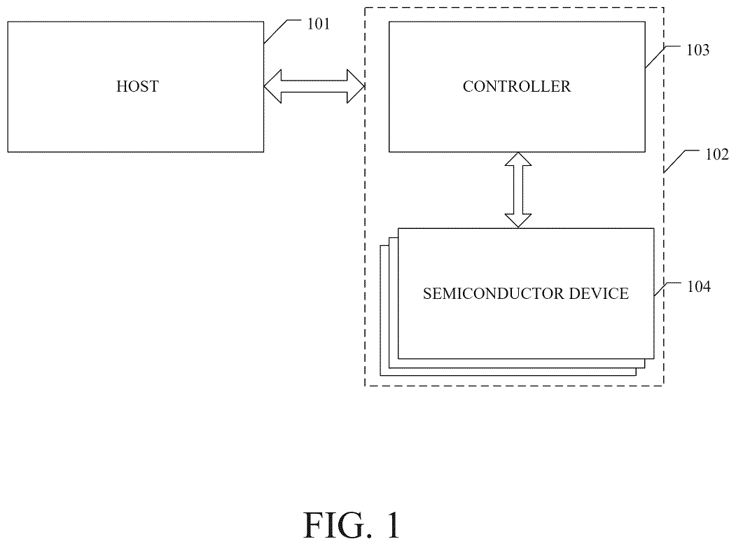

In some examples, the system in the foregoing examples may be the system 102 shown in FIG. 1, and the system 102 includes the controller 103 and the semiconductor device 104 coupled with the controller 103.

According to some implementations, as shown in FIG. 1, the controller 103 is coupled to the semiconductor device 104 and the host 101, and is configured to control operations of the semiconductor device 104, such as read, erase, program, compute operations, etc.

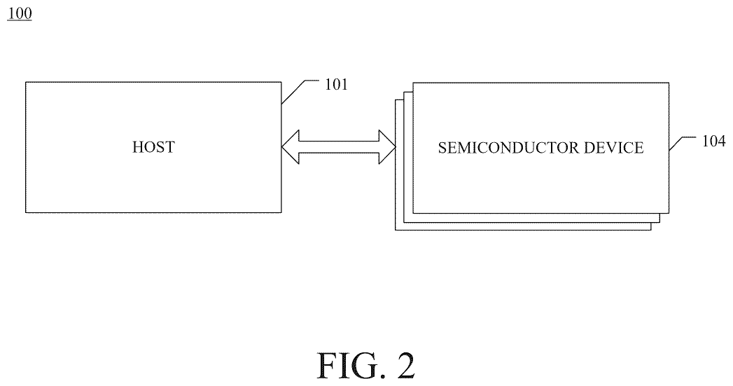

In some other examples, the system in the foregoing example may be the system 100 shown in FIG. 2, and the system 100 includes a host 101 and a semiconductor device 104 that may directly communicate with a host 101. The controller in the foregoing example may be a Central Processing Unit (CPU) in the host 101.

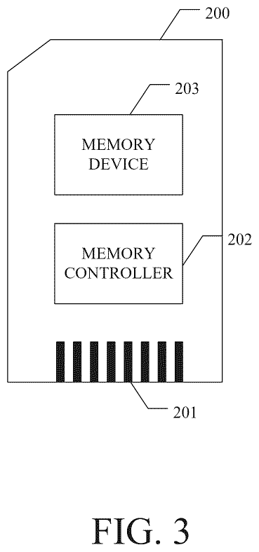

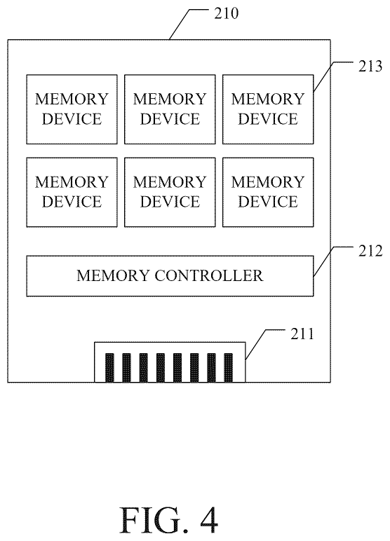

In an example as shown in FIG. 3, the system may be integrated into a memory card 200. The semiconductor device in the system may be a memory device 203 in a memory card 200, and the controller in the system may be a memory controller 202 in the memory card 200. The memory card 200 may be one of a compact flash card, a Smart Media Card (SMC), a Memory Stick (MS), a Multi-Media Card (MMC) (such as reduced-size MMC ((RS)-MMC), MMCmicro, embedded MMC (eMMC), etc.), a secure digital (SD) card (such as Mini SD card, Micro SD card, SD high capacity (DDHC) card, etc.), and a universal flash card. The memory card 200 may also include a memory card connector 201 that couples the memory card 200 with a host. In another example shown in FIG. 4, a system may be integrated into a solid state drive (SSD) 210. A semiconductor device in the system may be a memory device 213 in the solid state drive 210, and a controller in the system may be a memory controller 212 in the solid state drive 210. The solid state drive 210 may also include a solid state drive connector 211 that couples the solid state drive 210 with a host-side apparatus. In some implementations, storage capacity and/or operating speed of the solid state drive 210 is greater than storage capacity and/or operating speed of the memory card 200.

In some other examples, the system may be integrated into the terminal apparatus, and the controller may be a CPU of the terminal apparatus. Herein, the terminal apparatus may include, but not limited to, any terminal apparatus or portable terminal apparatus such as a mobile phone, a smart television, a smart stereo, a wearable apparatus, a tablet computer, a desktop computer, an all-in-one computer, a handheld computer, a notebook computer, a server, an ultra-mobile personal computer (UMPC), a netbook, a personal digital assistant (PDA), a laptop, a mobile computer, an augmented reality (AR) apparatus, a virtual reality (VR) apparatus, or an artificial intelligence (AI) apparatus.

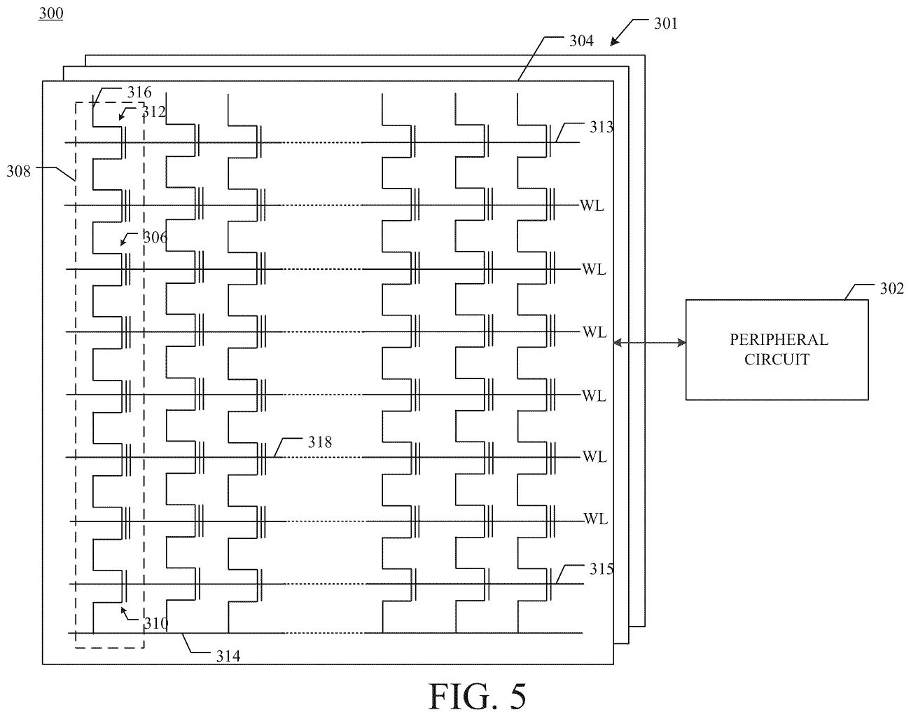

FIG. 5 is a first schematic diagram of composition of a semiconductor device according to an example of the present disclosure. The semiconductor device 300 may include a memory array 301 and a peripheral circuit 302 coupled to the memory array 301. The memory array 301 is a three-dimensional NAND memory array in which memory cells 306 are NAND memory cells, which are provided in the form of an array of memory strings 308, with each memory string 308 extending vertically. In some implementations, each memory string 308 includes a plurality of memory cells 306 coupled in series and vertically stacked. Each memory cell 306 can hold a continuous analog value, e.g., voltage or charge, depending on the number of electrons trapped by the memory cell 306. Each memory cell 306 may be a charge trapping type memory cell that includes a charge trapping transistor.

In some implementations, each memory cell 306 is a single level cell (SLC) that has two possible memory states and thus can store one bit of data. For example, a first memory state “O” may correspond to a first voltage range and a second memory state “1” may correspond to a second voltage range. In some implementations, each memory cell 306 is a multi-level cell capable of storing more than a single bit of data in four or more memory states, such as a Multi-Level Cell (MLC) storing two bits per cell, a Triple Level Cell (TLC) storing three bits per cell, or a Quad-Level Cell (QLC) storing four bits per cell.

As shown in FIG. 5, each memory string 308 may include a bottom select transistor 310 at its source end and a top select transistor 312 at its drain end. The bottom select transistor 310 and the top select transistor 312 may be configured to activate a selected memory string 308 during read and program operations. For example, during a program operation, the top select transistor 312 in the selected memory string 308 may be turned on and the top select transistor 310 in the unselected memory string 308 may be turned off, so that only the selected memory string 308 may be coupled to a bit line (BL) 316, e.g., the selected memory string 308 is activated.

In some implementations, sources of the memory strings 308 in a same memory block 304 may be coupled by a common source line (CSL) 314. In other words, all the memory strings 308 in the same memory block 304 have a array common source (ACS). According to some implementations, the top select transistor 312 of each memory string 308 is coupled to a respective bit line 316 from which data may be read or written via an output bus (not shown). In some implementations, each memory string 308 is configured to be selected or deselected by applying a select voltage (e.g., a voltage higher than a threshold voltage of the top select transistor 312) or a deselect voltage (e.g., OV) to the respective top select transistor 312 through one or more top select lines (TSL) 313 and/or by applying a select voltage (e.g., a voltage higher than a threshold voltage of the bottom select transistor 310) or a deselect voltage (e.g., OV) to the respective bottom select transistor 310 through one or more bottom select lines (BSL) 315.

As shown in FIG. 5, the memory string 308 may be organized into a plurality of memory blocks 304, and each of the plurality of memory blocks 304 may have the common source line 314. In some implementations, each memory block 304 is a basic data unit for an erase operation, e.g., all memory cells 306 in the same memory block 304 are erased at the same time. To erase the memory cells 306 in a selected memory block, the common source line 314 coupled to the selected memory block and an unselected memory block in the same plane as the selected memory block may be biased with an erase voltage. It will be appreciated that in some examples, an erase operation may be performed at a half memory block level, at a quarter memory block level, or at a level having any suitable number of memory blocks or any suitable fraction of memory blocks. The memory cells 306 of adjacent memory strings 308 may be coupled by a word line 318 that selects which row of memory cells 306 is to be affected by a read or program operation.

In some examples, the peripheral circuit 302 may include any suitable analog, digital, and mixed signal circuit for implementing operations on the memory array 301 by applying voltage and/or current signals to and sensing voltage and/or current signals from each target memory cell 306 through the bit lines 316, the word lines 318, the common source lines 314, the bottom select lines 315, and the top select lines 313. The peripheral circuit 302 may include various types of peripheral circuits formed using metal-oxide-semiconductor technology.

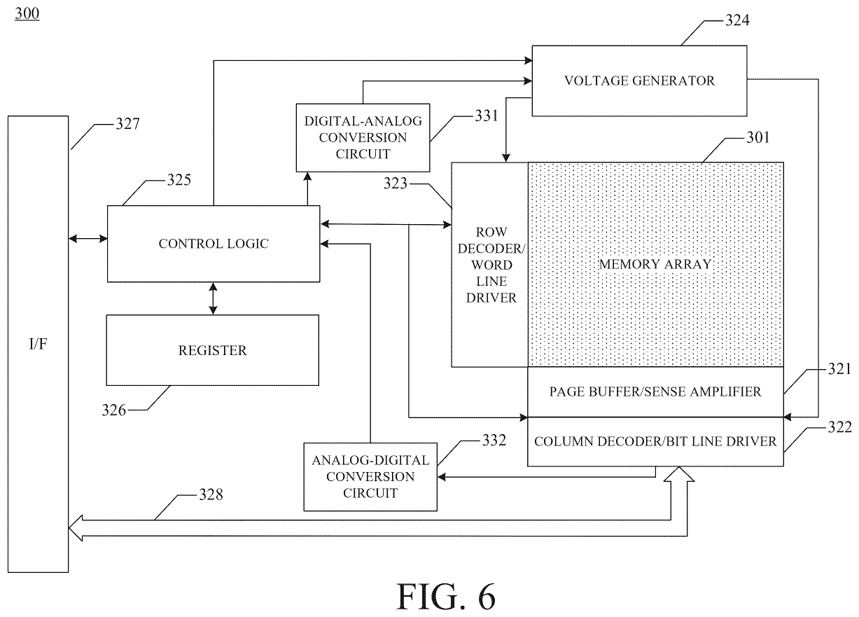

FIG. 6 is a second schematic diagram of composition of a semiconductor device according to an example of the present disclosure. As shown in FIG. 6, the peripheral circuit may include a page buffer/sense amplifier 321, a column decoder/bit line driver 322, a row decoder/word line driver 323, a voltage generator 324, a control logic 325, a register 326, a flash interface 327, and a data bus 328.

The page buffer/sense amplifier 321 may be configured to read data from and program (write) data to the memory array 301 according to control signals from the control logic 325. In an example, the page buffer/sense amplifier 321 may store a page of program data (write data) to be programmed to the memory array 301. In another example, the page buffer/sense amplifier 321 may perform a program verify operation to ensure that data has been correctly programmed into the memory cell coupled to the selected word line. In yet another example, the page buffer/sense amplifier 321 can also sense a low power signal from the bit line representing a data bit stored in the memory cell and amplify a small voltage swing to a recognizable logic level in a read operation. The column decoder/bit line driver 322 may be configured to be controlled by the control logic 325 and select one or more memory strings by applying a bit line voltage generated from the voltage generator 324.

The row decoder/word line driver 323 may be configured to be controlled by the control logic 325 and select/deselect the memory blocks of the memory array 301 and select/deselect the word lines of the memory blocks. The row decoder/word line driver 323 may also be configured to drive the word lines using word line voltages generated from the voltage generator 324. In some implementations, the row decoder/word line driver 323 may also select/deselect and drive the bottom and top select lines. As described in detail below, the row decoder/word line driver 323 is configured to perform a program operation on the memory cells coupled to the selected word line(s). The voltage generator 324 may be configured to be controlled by the control logic 325 and generate the word line voltages (e.g., read voltages, program voltages, pass voltages, local voltages, verify voltages, etc.), bit line voltages, and source line voltages to be supplied to the memory array 301.

The control logic 325 may be coupled to each circuit described above and configured to control the operation of each circuit. The registers 326 may be coupled to the control logic 325 and include a status register, a command register, and an address register for storing status information, command operation codes (OP codes), and command addresses for controlling operations of each peripheral circuit. Flash interface 327 may be coupled to the control logic 325 and act as a control buffer to buffer and relay control commands received from a host-side apparatus (not shown) to the control logic 325, and to buffer and relay the status information received from the control logic 325 to the memory controller. The flash interface 327 may also be coupled to the column decoder/bit line driver 322 via the data bus 328 and act as a data I/O interface and data buffer, to buffer and relay data to the memory array 301 or buffer or relay data from the memory array 301.

In some examples, with reference to FIG. 6, when the semiconductor device including the three-dimensional NAND memory is used as a compute-in-memory chip, the peripheral circuit may further include a digital-to-analog conversion circuit 331 and an analog-to-digital conversion circuit 332 in addition to the above mentioned circuits. The digital-to-analog conversion circuit 331 is connected to the control logic 325 and the voltage generator 324, and the analog-to-digital conversion circuit 332 is connected to the control logic 325 and the column decoder/BL driver 322. In an operation stage using the three-dimensional NAND memory, the control logic 325 may receive input data sent by the controller, the digital-to-analog conversion circuit 331 may convert the input data into a voltage signal, and the voltage generator 324 may generate a respective input voltage based on the voltage signal. An analog operation result obtained after the operation may be transmitted to the analog-to-digital conversion circuit 332, which may convert the analog operation result into a digital operation result.

In some examples, for the compute-in-memory chip, an operation between the input data and a weight matrix needs to be implemented, in which the input data may be an input vector or an input matrix composed of a plurality of elements, the weight matrix is composed of a plurality of weights, and each element in the input data needs to perform a multiply accumulate operation with the plurality of weights in the weight matrix, to obtain a corresponding element in an output data.

In order to implement the above operation function, the memory array in the semiconductor device may be configured to store the weight matrix. In an example, weights in the weight matrix may be written into the memory array according to a certain mapping rule, and each memory cell in the memory array may be configured to store a weight. In an inference operation stage, the semiconductor device may receive input data from the controller, the input data may be an input vector or an input matrix composed of a plurality of elements, and each element in the input data may be converted into an input voltage by using the digital-to-analog conversion circuit, and the input voltage is input to the memory array by using the bit line or the word line.

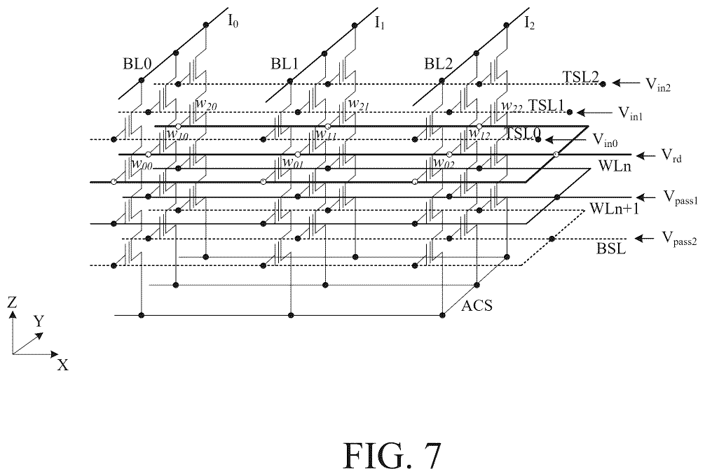

In some examples, FIG. 7 is a schematic diagram of inputting an input voltage by a word line into a memory block. As shown in FIG. 7, a memory cell coupled to a target word line WLn may be configured to store a weight data in a weight matrix, and in an example, a memory state corresponding to a threshold voltage of the memory cell may correspond to one weight data. An input voltage Vᵢₙ may be applied to the target word line WLn, and a pass voltage Vₚₐₛₛ may be applied to a non-target word lines coupled to the same memory block, so that the memory cells coupled to the non-target word lines are all in a turn-on state.

In this case, whether each memory string generates significant current depends only on whether the threshold voltage of the memory cell coupled to the target word line WLn is greater than the input voltage Vᵢₙ. When the input voltage Vᵢₙ is greater than the threshold voltage of the memory cell, the memory string to which the memory cell belongs is turned on and generates significant current. When the input voltage Vᵢₙ is less than the threshold voltage of the memory cell, the memory string to which the memory cell belongs is turned off and does not generate significant current. In this case, the current on the bit line may be detected at an end of each bit line coupled to the sensing circuit, respectively. Taking the bit line BL0 as an example, the current I₀ on the bit line BL0 corresponds to a result of multiplying the input data corresponding to the input voltage Vᵢₙ by weight w00, w10, w20 and accumulating the products.

In the above example, only one element in the input data can be operated with the weight matrix at one time, and the flexibility of the operation is low. When the input data is an input vector or an input matrix including a plurality of elements, the input voltages corresponding to the plurality of elements need to be sequentially input by the target word line WLn, resulting in a long operation period and low operation efficiency. Therefore, it may be beneficial to further optimize the operation scheme of the semiconductor device including the three-dimensional NAND memory.

In the examples of the present disclosure, the input voltage corresponding to the element in the input data may be input by a first select line, which may be one of the top select line and the bottom select line.

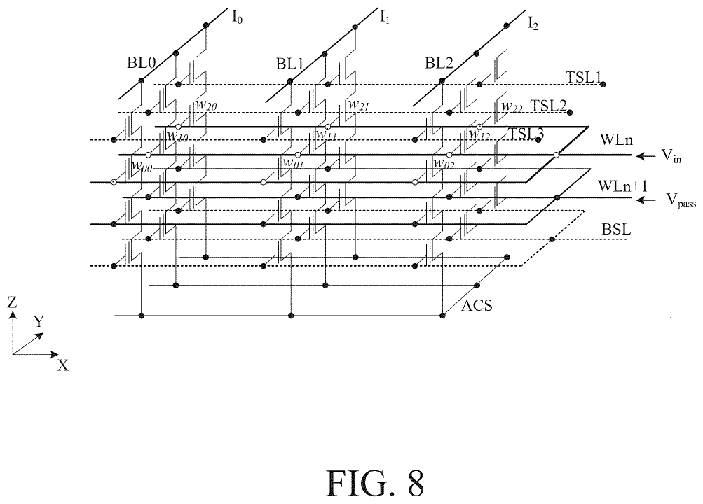

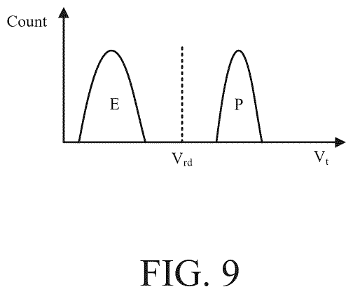

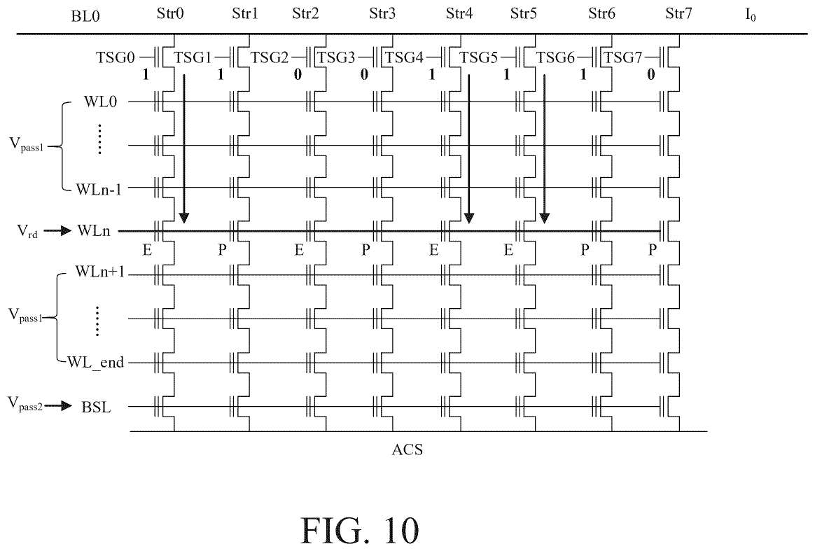

For instance, FIG. 8 is a schematic diagram of inputting an input voltage by a top select line into a memory block according to an example of the present disclosure. FIG. 9 is a schematic diagram of threshold voltage distributions of memory cells coupled to a target word line according to an example of the present disclosure. FIG. 10 is a schematic diagram of a plurality of memory strings coupled to one bit line according to an example of the present disclosure.

In some examples, as shown in FIG. 8, input voltages corresponding to elements in the input data may be input by a plurality of top select lines. In the operation stage using the semiconductor device, a read voltage V_{rd} may be applied to the target word line WLn coupled to the target memory block, and respective input voltages may be applied respectively to the plurality of top select lines coupled to the target memory block. For example, the input voltage Vᵢₙ₀, Vᵢₙ₁, Vᵢₙ₂ may be applied respectively to the top select lines TSL0, TSL1, and TSL2 coupled to the target memory block, and a first pass voltage may be applied to the non-target word lines coupled to the target memory block. For example, the first pass voltage Vₚₐₛₛ₁ may be applied to the word line WLn+1, and the second pass voltage may be applied to the bottom select line coupled to the target memory block, e.g., the second pass voltage Vₚₐₛₛ₂ may be applied to the bottom select line BSL. The operation result can be obtained by sensing the current on the bit line coupled to the target memory block and converting the current on the bit line. For example, by sensing the current I₀ on the bit line BL0 and converting the current I₀, a sum of the following three items can be obtained: a product of the weight w00 and the element corresponding to the input voltage Vᵢₙ₀, a product of the weight w10 and the element corresponding to the input voltage Vᵢₙ₁, and a product of the weight w20 and the element corresponding to the input voltage Vᵢₙ₂.

In some examples, the target memory block includes a plurality of memory cells. The memory cell may be configured to store N bits of weight data. The plurality of memory cells in the target memory block are configured to have 2^{N} memory states. The read voltage V_{rd} in the above example is between threshold voltage distributions corresponding to two adjacent memory states. Here, N is an integer greater than or equal to 1.

In some examples, as shown in FIG. 9, taking the memory cell configured to store 1-bit weight data as an example, the plurality of memory cells in the target memory block have a first memory state and a second memory state, in which a threshold voltage of the memory cell having the first memory state is less than a threshold voltage of the memory cell having the second memory state, a read voltage V_{rd} is greater than the threshold voltage of the memory cell having the first memory state and is less than the threshold voltage of the memory cell having the second memory state. Here, the memory cells in the target memory block may be a single level cell SLC storing one bit of data. The first memory state may be an erased state E, and the second memory state may be a programmed state P. The peripheral circuit may be configured to, before performing the operation, perform a program operation on the memory cells coupled to the target word line, and write the weights into the memory cells according to a certain mapping rule. For a single level cell, the process of writing the weights includes applying respective program voltages, to adjust threshold voltages of part of the memory cells coupled to the target word line to a range of threshold voltage distribution corresponding to the second memory state.

In some examples, referring to FIG. 10, taking the target memory block including eight memory strings coupled to the bit line BL0 as an example, among the memory cells coupled to the target word line WLn, four memory cells are in the first memory state (the erased state E), and the other four memory cells are in the second memory state (the programmed state P). The input data may be input by eight top select lines TSL0 to TSL7. In an example, the input data may be an input vector including eight elements, which may include five “1”s and three “0”s. The digital-to-analog conversion circuit may convert each element of the input vector into a corresponding voltage signal, and turn on the voltage generator to convert the voltage signal into an input voltage that needs to be applied on the top select line, and pass the input voltage to the top select line through a driver coupled to the top select line. In an example, eight input voltages may be simultaneously applied to the eight top select lines, respectively. The input voltage corresponding to “1” may turn on the top select transistors TSG0, TSG1, TSG4, TSG5 and TSG6 coupled to the top select lines TS0, TSL1, TSL4, TSL5 and TSL6, respectively, and the input voltage corresponding to “0” may turn off the top select transistors TSG2, TSG3 and TSG7 coupled to the top select lines TSL2, TSL3 and TSL7, respectively. In addition, a first pass voltage Vₚₐₛₛ₁ may be applied to the non-target word line coupled to the target memory block to turn on the memory cells coupled to the non-target word line; and a second pass voltage Vₚₐₛₛ₂ may be applied to the bottom select line BSL coupled to the target memory block to turn on the bottom select transistors coupled to the bottom select line BSL.

In this case, the current I₀ on the bit line BL0 is the sum of the output currents of the eight memory strings coupled to the bit line BL0, in which the input voltage on the top select line coupled to the memory strings Str0, Str4 and Str5 makes the top select transistors TSG0, TSG4 and TSG5 to be turned on, and the memory cells coupled to the target word line WLn in the memory strings Str0, Str4 and Str5 have the first memory state (the erased state E).

Therefore, the memory strings Str0, Str4 and Str5 are turned on, and may generate a current greater than or equal to a preset current. The current I₀ on the bit line BL0 is substantially equal to the sum of the output currents of the memory strings Str0, Str4 and Str5, and the multiple of the current I₀ relative to the current generated by any one of the memory strings Str0, Str4 and Str5 is approximately 3. If a weight value stored in the memory cell in the first memory state is equivalent to “1”, and a weight value stored in the memory cell in the second memory state is equivalent to “0”, then the operations performed by the eight memory strings coupled to the bit line BL0 may be equivalent to: 1*1+1*0+0*1+0*0+1*1+1*1+1*0+0*0=3.

In the operation scheme according to the above example, when there are Y+1 memory strings coupled to the bit line BLx in the target memory block, the Y+1 elements corresponding to the input voltages input by the Y+1 top select lines are do, (11, . . . , ay, respectively, and the weights stored in the Y+1 memory cells coupled to the target word line WLn are w₀, w₁, . . . , w_{Y}, respectively, then the operation result equivalent to the multiple of the current on the bit line BLx relative to the output current greater than or equal to the preset current may be a₀*w₀+α₁*w₁+ . . . +α_{Y}*w_{Y}. This multiply accumulate operation includes Y+1 multiplication operations, and the multipliers α₀, α₁, . . . , α_{Y} in the plurality of multiplication operations are different, and the multipliers of the multiplication operations performed by the memory strings coupled to different top select lines may be different for the entire target memory block, thereby improving the operation flexibility and facilitating the implementation of more complex operations through the semiconductor device.

In the operation solution provided in the above mentioned example, the operation result is obtained based on the multiple of the current on the bit line relative to the output current of the single memory string. When the threshold voltage of the memory cell coupled to the target word line is less than the read voltage, for example, when the memory cells coupled to the target word line are all in the erased state, and the input voltage applied to the top select line enables the top select transistor to be in the turn on state, the difference between the output currents of different memory strings should be less than a preset threshold, so that the operation result of the multiply accumulate operation obtained based on the current on the bit line is reliable. However, due to process errors in the manufacturing process, there may be a certain difference in performance of different memory string. For example, there may be a large difference between resistance of different memory strings, which may cause a large difference in output currents of different memory strings when being turned on, which may cause a decrease in reliability of the operation results.

In order to further improve the reliability of the semiconductor device as an compute-in-memory chip, the present disclosure proposes the following implementations.

The present disclosure provides a semiconductor device, including: a memory array, where the memory array includes a first memory string and a second memory string, the first memory string includes at least one first dummy memory cell; and a peripheral circuit, coupled to the memory array, and configured to: perform a program operation on the at least one first dummy memory cell, so that a threshold voltage of the at least one first dummy memory cell is adjusted from an initial threshold to a first target threshold, where, when the threshold voltage of the at least one first dummy memory cell reaches the first target threshold, a difference between a current of the first memory string and a current of the second memory string is less than or equal to a preset threshold.

In the examples of the present disclosure, in order to improve the reliability of the semiconductor device as an compute-in-memory chip, before the operation is performed by using the semiconductor device, the difference between the currents of different memory strings may be reduced by adjusting the threshold voltages of the dummy memory cells in the memory strings. Here, the current of the memory string may be the current on the bit line sensed when only this memory string among a plurality of memory strings connected to a bit line is turned on.

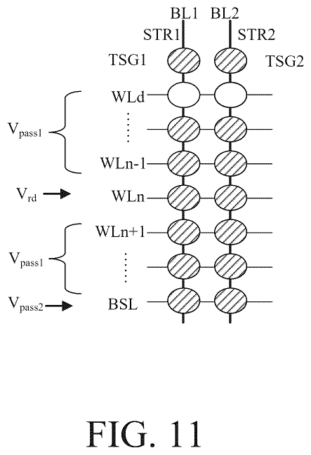

In some examples, as shown in FIG. 11, the memory array includes a first memory string STR1 and a second memory string STR2, in which the first memory string STR1 is coupled to a bit line BL1, and the second memory string STR2 is coupled to a bit line BL2. The first memory string STR1 includes at least one first dummy memory cell coupled to a dummy word line WLd, and the second memory string STR2 includes at least one second dummy memory cell coupled to a dummy word line WLd.

It should be noted that, in the examples of the present disclosure, the first memory string and the second memory string may represent two types of memory strings in a target memory block, where the first memory string may represent a memory string with a lower resistance and a corresponding higher current, and the second memory string may represent a memory string with a higher resistance and a corresponding lower current. Here, for case of description, one first memory string STR1 and one second memory string STR2 are taken as an example, in which the first memory string STR1 and the second memory string STR2 are respectively coupled to different bit lines. It can be understood that an operation performed by the peripheral circuit on the first memory string STR1 may be an operation performed on all memory strings with lower resistance in the target memory block, and an operation performed by the peripheral circuit on the second memory string STR2 may be an operation performed on all memory strings with higher resistance in the target memory block. The first memory string STR1 and the second memory string STR2 may also be memory strings coupled to the same bit line.

In addition, in the examples of the present disclosure, a dummy memory cell refers to a memory cell in a memory string that is not used for storing a weight. In FIG. 11, for example, a case in which the first memory string STR1 and the second memory string STR2 each include one dummy memory cell coupled to a dummy word line WLd, and the dummy memory cell is coupled between the bit line and other memory cells in the memory string is taken as an example, but the disclosure is not limited thereto. In some other examples, the dummy memory cell may be coupled between the common source and other memory cells in the memory string, or the dummy memory cell may be coupled between the memory cells in the memory string. The present disclosure does not limit the arrangement and positions of the dummy memory cells and the number of the dummy memory cells in the memory string.

In some examples, a current of the memory string may be measured before a program operation is performed on the first dummy memory cell. In an example, as shown in FIG. 11, the peripheral circuit may be configured to: apply a read voltage V_{rd} to a target word line WLn in a target memory block; apply a first pass voltage Vₚₐₛₛ₁ to a non-target word line in the target memory block; apply respective input voltages to a plurality of first select lines in the target memory block respectively; apply a second pass voltage Vₚₐₛₛ₂ to a plurality of second select lines in the target memory block respectively; and sense a current on a bit line coupled to the target memory block to obtain a current of the memory string in the target memory block. Here, the first select line may be one of the top select line and the bottom select line, and the second select line may be the other of the top select line and the bottom select line. In examples of the present disclosure, a case in which the first selection line is the top selection line and the second selection line is the bottom selection line is taken as an example.

In the examples of the present disclosure, the current of the memory string may be measured using a scheme similar to the operation stage. In this case, the memory cells coupled to the target word line WLn may all be in the first memory state (the erased state), and the peripheral circuit is configured to: apply a respective input voltage to a first select line coupled to a memory string in the target memory block to turn on the memory string; and apply respective input voltages to the first select lines coupled to other memory strings coupled to the same bit line to which the memory string is coupled to turn off the other memory strings. For example, when measuring the current of the first memory string STR1, the input voltage applied to the first select line coupled to the first memory string STR1 can turn on the top select transistor in the first memory string STR1.

Then, in a case where the read voltage V_{rd} is applied to the target word line WLn, the first pass voltage Vₚₐₛₛ₁ is applied to the non-target word line, and the second pass voltage Vₚₐₛₛ₂ is applied to the second select line, the first memory string STR1 may be turned on, and only the first memory string STR1 among the plurality of memory strings coupled to the bit line BL1 is turned on. In this case, the current of the first memory string STR1 can be obtained by sensing the current on the bit line BL1.

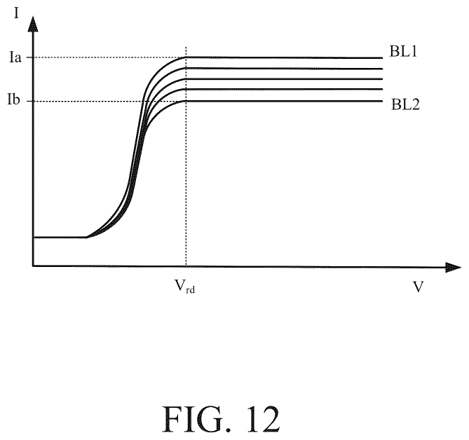

In some examples, the current of each memory string in the target memory block may be measured by the above method. Taking a case in which the first memory string STR1 is a memory string with a smaller resistance and the second memory string STR2 is a memory string with a larger resistance as an example, as shown in FIG. 12, before the program operation is performed on the at least one first dummy memory cell, the current of the first memory string STR1 is Ia, the current of the second memory string STR is Ib, Ia is greater than Ib, and the difference between Ia and Ib is greater than the preset threshold It, that is, the difference between the current Ia of the first memory string STR1 and the current Ib of the second memory string STR2 is large, which may affect the reliability of the operation.

In an example of the present disclosure, the peripheral circuit may be configured to perform a program operation on at least one dummy memory cell in the first memory string STR1, so that a threshold voltage of the at least one dummy memory cell is adjusted from an initial threshold to a first target threshold Vt1, and in a case where the threshold voltage of the at least one first dummy memory cell reaches the first target threshold Vt1, a difference between a current of the first memory string STR1 and a current of the second memory string STR2 is less than or equal to the preset threshold It.

In an example, the preset threshold It should be less than Ib/2.

In some examples, performing the program operation on the at least one first dummy memory cell includes performing the program operation on the first dummy memory cell by an increment step pulse program (ISPP) approach. During a process of the increment step pulse program, a bit line voltage (e.g., a ground voltage V_{SS}) is applied to the bit line BL1 coupled to the first memory string STR1, and an increasing program voltage is applied to the dummy word line WLd coupled to the at least one first dummy memory cell to perform a program operation on the at least one first dummy memory cell. The difference between two adjacent program voltages is a step size of a step pulse. Between two adjacent program pulses, a program-verify operation is performed to apply a verify voltage to the dummy word line WLd to determine whether the threshold voltage of the first dummy memory cell reaches the first target threshold Vt1. If the first dummy memory cell fails to pass the program-verify operation, the program-verify operation is continued until the threshold voltage of the first dummy memory cell reaches the first target threshold Vt1.

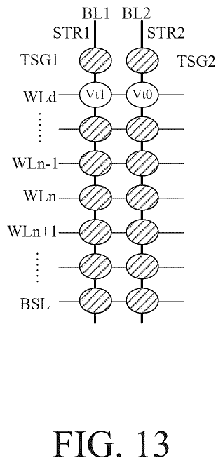

In some examples, referring to FIG. 13, in a case where the threshold voltage of at least one first dummy memory cell in the first memory string STR1 is adjusted to the first target threshold Vt1, the threshold voltage of at least one second dummy memory cell in the second memory string STR2 remains at the initial threshold Vt0. Here, the initial threshold Vt0 is less than the first target threshold Vt1.

In the examples of the present disclosure, by performing the program operation on the at least one first dummy memory cell in the first memory string, the threshold voltage of the first dummy memory cell may be increased. In a case where the magnitude of the pass voltage applied to the dummy word line remains unchanged, the resistance of the first memory string in a turn-on state may be increased, the current of the first memory string may be reduced, and the difference between the current of the first memory string and the current of the second memory string may be reduced, thereby improving the reliability of the operation result.

In some examples, the peripheral circuit is configured to: perform a program operation on the at least one second dummy memory cell, so that a threshold voltage of the at least one second dummy memory cell is adjusted from an initial threshold to a second target threshold Vt2; in a case where the threshold voltage of the at least one first dummy memory cell reaches the first target threshold Vt1 and the threshold voltage of the at least one second dummy memory cell reaches the second target threshold Vt2, the difference between the current of the first memory string STR1 and the current of the second memory string STR2 is less than or equal to the preset threshold It.

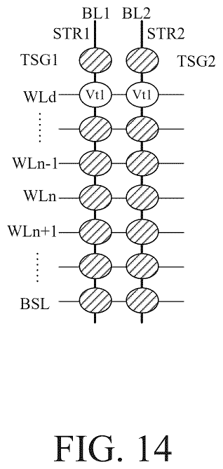

In some examples, referring to FIG. 14, the first target threshold Vt1 is equal to the second target threshold Vt2; and the peripheral circuit is configured to: perform a program operation on the first dummy memory cell in the first memory string STR1 and the second dummy memory cell in the second memory string STR2, to adjust both the threshold voltage of the first dummy memory cell and the threshold voltage of the second dummy memory cell to the first target threshold Vt1, thereby simultaneously increasing the resistance of the first memory string STR1 and the second memory string STR2. Here, the first dummy memory cell in the first memory string STR1 and the second dummy memory cell in the second memory string STR2 may be coupled to the same dummy word line WLd, and the program operation may be performed on the first dummy memory cell and the second dummy memory cell simultaneously.

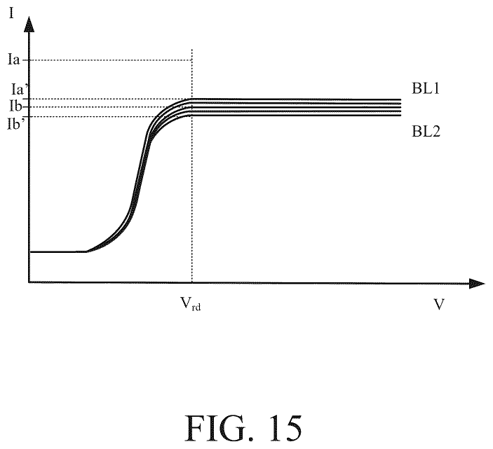

In some implementations, referring to FIG. 12 and FIG. 15, by increasing the threshold voltages of the dummy memory cells in the memory string to the first target threshold Vt1, the resistance of the memory string may be increased, and the current of the memory string when the read voltage V_{rd} is applied to the target word line may be reduced. For example, the current of the first memory string STR1 is reduced from Ia to Ia′, and the current of the second memory string STR2 is reduced from Ib to Ib′, at the same time, the difference between the current of the first memory string and the current of the second memory string can also be narrowed down, thereby improving the reliability of the operation result.

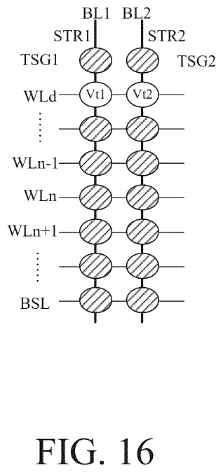

In some examples, referring to FIG. 16, the peripheral circuit is further configured to: perform a program operation on the at least one second dummy memory cell, so that a threshold voltage of the at least one second dummy memory cell reaches a second target threshold Vt2, and the first target threshold Vt1 is greater than the second target threshold Vt2.

In some examples, both the first target threshold Vt1 and the second target threshold Vt2 are higher than the target threshold Vt0, and the first target threshold Vt1 is within the range of the threshold voltage distribution corresponding to the programmed state, and the second target threshold Vt2 may still be within the range of the threshold voltage distribution corresponding to the erased state.

In the examples of the present disclosure, the program operation may be performed on the first dummy memory cell in the first memory string and the second dummy memory cell in the second memory string to adjust the threshold voltage of the first dummy memory cell to the first target threshold, and adjust the threshold voltage of the second dummy memory cell to the second target threshold, and the first target threshold is greater than the second target threshold, such that on the basis of increasing the resistance of the first memory string and the resistance of the second memory string, the resistance of the first memory string with a smaller resistance before the program operation is performed on the first and second dummy memory cell may be increased with a greater degree than the resistance of the second memory string with a larger resistance, to further reduce the difference between the current of the first memory string and the current of the second memory string, and improve the reliability of the operation result.

In the examples of the present disclosure, before the operation is performed by using the semiconductor device, the resistance of the memory strings in the target memory block may be adjusted by using the method provided in any one of the above examples, so that the differences between the currents of different memory strings are all less than the preset threshold. Thus, in the operation stage using the semiconductor device, the output currents of the different memory strings in the turn-on state may be substantially equal, thereby improving the reliability of the operation result of the multiply accumulate operation obtained based on the multiple of the current on the bit line relative to the output current of a single memory string.

In some examples, the semiconductor device in the above examples includes a three-dimensional NAND memory.

In the examples of the present disclosure, the semiconductor device in any of the above examples can be obtained without greatly modifying the three-dimensional NAND memory as the compute-in-memory chip, that is, the effect of improving the operation accuracy can be achieved without increasing the area of the circuit and the chip.

In some examples, the semiconductor device in the above mentioned includes a first semiconductor structure and a second semiconductor structure, in which the memory array is located in the first semiconductor structure, the peripheral circuit is located in the second semiconductor structure, and the first semiconductor structure and the second semiconductor structure are stacked in a thickness direction of the semiconductor device.

In some examples, the semiconductor device includes the first semiconductor structure, a hybrid bonding layer and the second semiconductor structure stacked in the thickness direction of the semiconductor device; the memory array is located in the first semiconductor structure, the peripheral circuit is located in the second semiconductor structure, and the peripheral circuit is coupled to the memory array through a bonding structure in the hybrid bonding layer.

In the examples of the present disclosure, the first semiconductor structure and the second semiconductor structure of the semiconductor device may be formed by bonding two wafers, for example, the first semiconductor structure may be formed on one wafer, the second semiconductor structure may be formed on the other wafer, and then the two wafers are bonded to form the hybrid bonding layer between the first semiconductor structure and the second semiconductor structure. In some other examples, the first semiconductor structure and the second semiconductor structure of the semiconductor device may also be formed on the same wafer, but the first semiconductor structure and the second semiconductor structure are stacked along the thickness direction of the semiconductor device. The architecture in which the first semiconductor structure and the second semiconductor structure are stacked along the thickness direction of the semiconductor device can further save the area of the semiconductor device.

Based on a concept similar to the foregoing semiconductor device, the present disclosure further provides a system, including: at least one semiconductor device according to any one of the foregoing implementations; and a controller, coupled to the at least one semiconductor device and configured to send input data to the semiconductor device and receive an operation result of the semiconductor device.

In some examples, the operation result of the semiconductor device may be an operation result obtained based on the current on the bit line in the above examples.

In some other examples, the peripheral circuit in the semiconductor device may be further configured to perform a logical operation on the operation result obtained based on the current on the bit line, and the operation result of the semiconductor device may be an operation result obtained by performing a logical operation again on the operation result obtained based on the current on the bit line in the foregoing example.

In some examples, for specific composition and function implementation of the system, reference may be made to the foregoing descriptions of FIG. 1 to FIG. 6.

Based on a concept similar to the foregoing semiconductor device, the present disclosure further provides an operation method of a semiconductor device, including: performing a program operation on at least one first dummy memory cell included in a first memory string included in the semiconductor device, so that a threshold voltage of the at least one first dummy memory cell is adjusted from an initial threshold to a first target threshold, where, in a case that the threshold voltage of the at least one first dummy memory cell reaches the first target threshold, a difference between a current of the first memory string and a current of a second memory string included in the semiconductor device is less than or equal to a preset threshold.

In some examples, the operation method further includes: causing a threshold voltage of at least one second dummy memory cell included in the second memory string included in the semiconductor device remain at the initial threshold; where, before the program operation is performed on the at least one first dummy memory cell, a current of the first memory string is greater than a current of the second memory string, and a difference between the current of the first memory string and the current of the second memory string is greater than the preset threshold.

In some examples, the operation method further includes: performing a program operation on at least one second dummy memory cell included in the second memory string, so that a threshold voltage of the at least one second dummy memory cell is adjusted from the initial threshold to a second target threshold; where, in a case where the threshold voltage of the at least one first dummy memory cell reaches the first target threshold and the threshold voltage of the at least one second dummy memory cell reaches the second target threshold, a difference between a current of the first memory string and a current of the second memory string is less than or equal to the preset threshold.

In some examples, the first target threshold is equal to the second target threshold.

In some examples, the first target threshold is greater than the second target threshold; and before the program operation is performed on the at least one first dummy memory cell and the at least one second dummy memory cell, the current of the first memory string is greater than the current of the second memory string, and a difference between the current of the first memory string and the current of the second memory string is greater than the preset threshold.

In some examples, the operation method further includes: applying a read voltage to a target word line in a target memory block included in the semiconductor device; applying a first pass voltage to a non-target word line in the target memory block; applying respective input voltages to a plurality of first select lines in the target memory block respectively; applying second pass voltages to a plurality of second select lines in the target memory block respectively; and sensing a current on a bit line coupled to the target memory block to obtain a current of a memory string in the target memory block, where the target memory block includes the first memory string and the second memory string.

In some examples, the applying respective input voltages to the plurality of first select lines in the target memory block respectively includes: applying a respective input voltage to the first select line coupled to a memory string in the target memory block to turn on the memory string; and applying respective input voltages to the first select lines coupled to other memory strings coupled to the same bit line to which the memory string is coupled to turn off the other memory strings.

In some examples, the target memory block includes a plurality of memory cells; each memory cell is configured to store N bits of weight data, the plurality of memory cells are configured to have 2^{N} memory states, and the read voltage is between threshold voltage distributions corresponding to two adjacent memory states; and N is an integer greater than or equal to 1.

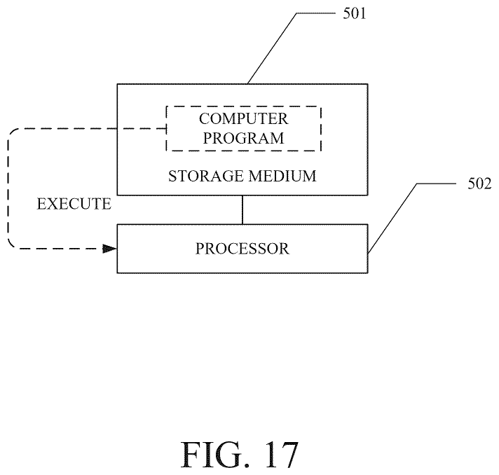

Based on a concept similar to the operation method of the semiconductor device described above, the present disclosure further provides a computer-readable storage medium, and FIG. 17 is a schematic diagram of a computer-readable storage medium according to an example of the present disclosure. The computer-readable storage medium 501 stores a computer program thereon, and when the computer program is executed by the processor 502, the operation method of the semiconductor device in any of the above examples may be implemented.

In some implementations, the computer-readable storage medium 501 may be a memory such as a ferromagnetic random access memory (FRAM), a read only memory (ROM), a programmable read-only memory (PROM), an erasable programmable read-only memory (EPROM), an electrically erasable programmable read-only memory (EEPROM), a flash memory, a magnetic surface memory, an optical disc, or a compact disc read-only memory (CD-ROM); or may be various apparatus including one or any combination of the foregoing memory device.

It should be understood that “one example” or “an example” mentioned throughout the specification means that particular features, structures, or characteristics related to the example are included in at least one example of the present disclosure. Therefore, “in one example” or “in an example” appearing throughout the specification does not necessarily refer to the same example. Furthermore, the particular features, structures, or characteristics may be combined in any suitable manner in one or more examples. It should be understood that, in various examples of the present disclosure, the sequence numbers of the above processes do not mean an execution sequence, and the execution sequence of the respective processes should be determined by their function and internal logic, and should not constitute any limitation on the implementation process of the examples of the present disclosure. The above mentioned sequence numbers of the examples of the present disclosure are only for description, and do not represent the preference of the examples.

The features disclosed in several device examples provided by the present disclosure may be arbitrarily combined without conflict to obtain new device examples.

The methods disclosed in the several method examples provided in the present disclosure may be arbitrarily combined without conflict to obtain new method examples.

What are described above are only the particular implementations of the disclosure and the scope of the present disclosure is not limited thereto; those skilled who are familiar with the this field can easily think of changes or substitutions within the scope disclosed in this disclosure, which should be included in the scope of this disclosure.

What is claimed is:

1. A semiconductor device, comprising:
a memory array comprising a first memory string and a second memory string, the first memory string comprising at least one first dummy memory cell; and
a peripheral circuit coupled to the memory array and configured to perform a program operation on the at least one first dummy memory cell, such that a threshold voltage of the at least one first dummy memory cell is adjusted from an initial threshold to a first target threshold;
wherein in a case where the threshold voltage of the at least one first dummy memory cell reaches the first target threshold, a difference between a current of the first memory string and a current of the second memory string is less than or equal to a preset threshold.

2. The semiconductor device according to claim 1, wherein:
the second memory string comprises at least one second dummy memory cell;
a threshold voltage of the at least one second dummy memory cell remains at the initial threshold;
before performing the program operation on the at least one first dummy memory cell, the current of the first memory string is greater than the current of the second memory string; and
the difference between the current of the first memory string and the current of the second memory string is greater than the preset threshold.

3. The semiconductor device according to claim 1, wherein:
the second memory string comprises at least one second dummy memory cell;
the peripheral circuit is configured to perform a program operation on the at least one second dummy memory cell, such that a threshold voltage of the at least one second dummy memory cell is adjusted from the initial threshold to a second target threshold; and
in a case where the threshold voltage of the at least one first dummy memory cell reaches the first target threshold and the threshold voltage of the at least one second dummy memory cell reaches the second target threshold, the difference between the current of the first memory string and the current of the second memory string is less than or equal to the preset threshold.

4. The semiconductor device according to claim 3, wherein the first target threshold is equal to the second target threshold.

5. The semiconductor device according to claim 3, wherein:
the first target threshold is greater than the second target threshold;
before performing the program operation on the at least one first dummy memory cell and the at least one second dummy memory cell, the current of the first memory string is greater than the current of the second memory string; and
the difference between the current of the first memory string and the current of the second memory string is greater than the preset threshold.

6. The semiconductor device according to claim 1, wherein the peripheral circuit is further configured to:
apply a read voltage to a target word line in a target memory block;
apply a first pass voltage to a non-target word line in the target memory block;
apply respective input voltages to a plurality of first select lines in the target memory block respectively;
apply a second pass voltage to a plurality of second select lines in the target memory block respectively; and
sense a current on a bit line coupled to the target memory block to obtain a current of a memory string in the target memory block;
wherein the target memory block comprises the first memory string and the second memory string.

7. The semiconductor device according to claim 6, wherein the peripheral circuit is configured to:
apply a respective input voltage to the first select line coupled to one memory string in the target memory block to turn on the memory string; and
apply respective input voltages to the first select lines coupled to other memory strings coupled to the same bit line to which the memory string is coupled to turn off the other memory strings.

8. The semiconductor device according to claim 6, wherein:
the target memory block comprises a plurality of memory cells;
the memory cell is configured to store N bits of weight data;
the plurality of memory cells in the target memory block are configured to have 2^{N} memory states;
the read voltage is between threshold voltage distributions corresponding to two adjacent memory states; and
N is an integer greater than or equal to 1.

9. The semiconductor device according to claim 6, wherein the first select line is one of a top select line and a bottom select line, and the second select line is the other of the top select line and the bottom select line.

10. The semiconductor device according to claim 1, wherein:
the peripheral circuit comprises an analog-to-digital conversion circuit, a digital-to-analog conversion circuit, a voltage generator, a column decoder, and a control logic;
the analog-to-digital conversion circuit is coupled to the column decoder and the control logic; and
the digital-to-analog conversion circuit is coupled to the voltage generator and the control logic.

11. The semiconductor device according to claim 1, wherein the semiconductor device comprises a three-dimensional NAND memory.

12. The semiconductor device according to claim 1, wherein:
the semiconductor device comprises a first semiconductor structure, a hybrid bonding layer, and a second semiconductor structure that are stacked in a thickness direction of the semiconductor device, with the hybrid bonding layer located between the first semiconductor structure and the second semiconductor structure;
the memory array is located in the first semiconductor structure, the peripheral circuit is located in the second semiconductor structure; and
the memory array and the peripheral circuit are coupled through a bonding structure in the hybrid bonding layer.

13. A system, comprising:
at least one semiconductor device, comprising:
a memory array comprising a first memory string and a second memory string, the first memory string comprising at least one first dummy memory cell; and
a peripheral circuit coupled to the memory array and configured to perform a program operation on the at least one first dummy memory cell, such that a threshold voltage of the at least one first dummy memory cell is adjusted from an initial threshold to a first target threshold;
wherein in a case where the threshold voltage of the at least one first dummy memory cell reaches the first target threshold, a difference between a current of the first memory string and a current of the second memory string is less than or equal to a preset threshold; and
a controller coupled to the at least one semiconductor device and configured to send input data to the semiconductor device and receive an operation result of the semiconductor device.

14. A method of operating a semiconductor device, comprising:
performing a program operation on at least one first dummy memory cell included in a first memory string included in the semiconductor device, such that a threshold voltage of the at least one first dummy memory cell is adjusted from an initial threshold to a first target threshold;
wherein in a case where the threshold voltage of the at least one first dummy memory cell reaches the first target threshold, a difference between a current of the first memory string and a current of a second memory string included in the semiconductor device is less than or equal to a preset threshold.

15. The method according to claim 14, further comprising:
causing a threshold voltage of at least one second dummy memory cell included in the second memory string included in the semiconductor device to remain at the initial threshold;
wherein before performing the program operation on the at least one first dummy memory cell, the current of the first memory string is greater than the current of the second memory string, and the difference between the current of the first memory string and the current of the second memory string is greater than the preset threshold.

16. The method according to claim 14, further comprising:
performing a program operation on at least one second dummy memory cell included in the second memory string, such that a threshold voltage of the at least one second dummy memory cell is adjusted from the initial threshold to a second target threshold;
wherein in a case where the threshold voltage of the at least one first dummy memory cell reaches the first target threshold and the threshold voltage of the at least one second dummy memory cell reaches the second target threshold, the difference between the current of the first memory string and the current of the second memory string is less than or equal to the preset threshold.

17. The method according to claim 16, wherein the first target threshold is equal to the second target threshold.

18. The method according to claim 16, wherein:
the first target threshold is greater than the second target threshold;
before performing the program operation on the at least one first dummy memory cell and the at least one second dummy memory cell, the current of the first memory string is greater than the current of the second memory string; and
the difference between the current of the first memory string and the current of the second memory string is greater than the preset threshold.

19. The method according to claim 14, further comprising:
applying a read voltage to a target word line in a target memory block included in the semiconductor device;
applying a first pass voltage to a non-target word line in the target memory block;
applying respective input voltages to a plurality of first select lines in the target memory block respectively;
applying a second pass voltage to a plurality of second select lines in the target memory block; and
sensing a current on a bit line coupled to the target memory block to obtain a current of a memory string in the target memory block;
wherein the target memory block comprises the first memory string and the second memory string.

20. The method according to claim 19, wherein the applying the respective input voltages to the plurality of first select lines in the target memory block respectively comprises:
applying a respective input voltage to the first select line coupled to one memory string in the target memory block to turn on the memory string; and
applying respective input voltages to the first select lines coupled to other memory strings coupled to the same bit line to which the memory string is coupled to turn off the other memory strings.
